(19) United States
(12) Patent Application Publication
(10) Pub. No.: US 2007/0137886 A1
(43) Pub. Date: Jun. 21, 2007

(54) METHOD FOR PARTIAL REPLACEMENT OF A CIRCUIT BOARD

(76) Inventor: Chen-Hsiang Yen, Taoyuan City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 11/306,266

(22) Filed: Dec. 21, 2005

(51) Int. Cl. H05K 1/00

(52) U.S. Cl. 174/250

(57) ABSTRACT

The present invention relates to a method for partial replacement of a circuit board, comprising: providing a first carrier board and a replaced board which has a second circuit board and a plurality of linkage arm which keeps the second circuit board at the replaced board; cutting a lifted board from the first carrier board to make a void part at the first carrier board; and combining the replaced board with the first carrier board at the void part. Base on the present invention said above, if the first carrier board related to the present invention has more first circuit boards, the method of the present invention still works and each first circuit board can be replaced with a second circuit board of the replaced board to make the first carrier board complete.

### BACKGROUND OF THE INVENTION

1. Field of the Invention

The present invention relates to a method for partial replacement of a circuit board, and in particular to practice repair of the circuit board.

2. Discussion of Related Art

About a prior art of a carrier board which has several distinguishing parts with circuits respectively, and the carrier board would be discarded while any part of the carrier board has some faults. At this result, waste is occurred and cost is increased while some parts of the discarded carrier board still works. To avoid the waste and the cost increase, a disclosed art of the carrier board has a method for manufacture of a carrier board, and the method comprises: producing a carrier board which has a plurality of circuit board formed by a pressing process or a CNC center and fixed by linkage arms; testing each circuit board on the carrier board; lifting of any faulty circuit board by destroying the linkage arms; modifying the linkage arms; preparing a replaced board to substitute the faulty circuit board; and combining the replaced board with the carrier board to repair the carrier board.

Because electric products are popularized and varied, the contour of a circuit board must be according to requirements of these electric products. Therefore, the contour which is a circle, a polygon, a parabola, a streamline shape, or any other shape brings that the manufacture of the circuit board is more difficult and the circuit board would be damage easily.

Moreover, the circuit boards is fixed at the carrier board by the linkage arms so that the replacement of any circuit board is more difficult from the cutting process and the combining process.

Base on the reasons above, the prior arts doesn't provide any solution for the repair of the circuit board with complicated contour. Thus the present invention is aimed to provide a method for partial replacement of a circuit board that overcomes the drawbacks of the prior art.

### SUMMARY OF THE INVENTION

A primary objective of the present invention is to provide a method for partial replacement of a circuit board with contour which is a circle, a polygon, a parabola, a streamline shape, or any other shape.

A second objective of the present invention is to provide a method for partial replacement of a circuit board for repairing the circuit board by replacing with a replace board, to avoid the waste and the cost increase happening, and to conduce the competitiveness.

A third objective of the present invention is to provide a method for partial replacement of a circuit board that has engaged mechanism between the circuit board and the replace board for better combination and assembly.

A fourth objective of the present invention is to provide a method for partial replacement of a circuit board that has fast process to complete cutting the circuit board and combining between the circuit board and the replace board.

The present invention relates to a method for partial replacement of a circuit board, comprising: providing a first carrier board and a replaced board which has a second circuit board and a plurality of linkage arm which keeps the second circuit board at the replaced board; cutting a lifted board from the first carrier board to make a void part at the first carrier board; and combining the replaced board with the first carrier board at the void part. Base on the present invention said above, if the first carrier board related to the present invention has more first circuit boards, the method of the present invention still works and each first circuit board can be replaced with a second circuit board of the replaced board to make the first carrier board complete.

About the method for partial replacement of a circuit board said above, the cutting processes of the replaced board and the lifted board are made contours thereof be engaged. In an embodiment, the cutting machine cuts a first carrier board vertically to release a scrapped area so that the first carrier board has a void part. A replaced board is made from another carrier board by the same cutting process which produces the void part of the first carrier board. The replaced board has a second circuit board and a plurality of linkage arm which keeps the first circuit board at the replaced board, and the replaced board has a first engaged structure at an outline thereof. Moreover, at an outline of the void part the first carrier board has a second engaged structure according to the first engaged structure of the replaced board so that the replaced board combines with the first carrier board at the void part by engagement of the first circuit board and the second engaged structure.

The present invention will become more obvious from the following description when taken in connection with the accompanying drawings, which show, for purposes of illustration only, a preferred embodiment in accordance with the present invention.

### BRIEF DESCRIPTION OF THE DRAWINGS

These and other features, aspects and advantages of the present invention will become better understood with regard to the following description, appended claims and accompanying drawings where:

FIG. 1 is a flow chart of a method for partial replacement of a circuit board in accordance with the present invention;

FIG. 2 is a perspective view which a carrier board releases a first circuit board in accordance with the present invention;

FIG. 3 is a perspective view which another carrier board releases a second circuit board in accordance with the present invention;

FIG. 4 is a perspective view which a carrier board combines with the second circuit board in accordance with the present invention;

FIG. 5 is a perspective view in an embodiment which a carrier board combines with a second circuit board in accordance with the present invention;

FIG. 6 is a perspective view in another embodiment which a carrier board combines with a second circuit board in accordance with the present invention.

### DETAILED DESCRIPTION ON THE INVENTION

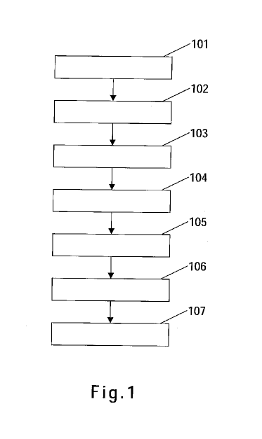

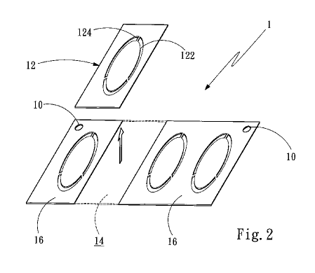

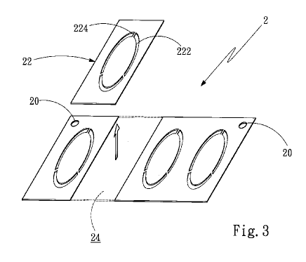

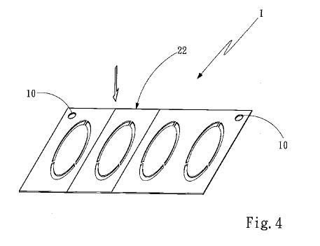

With reference to FIG. 1, FIG. 2, FIG. 3 and FIG. 4, a method for partial replacement of a circuit board in accordance with the present invention includes: step 101, providing a first carrier board 1 showed as FIG. 2, a second carrier board 2 showed as FIG. 3, an aligning mechanism, a cutting machine (no figure shows), and an assembling machine (no figure shows); step 102, aligning a plurality of first pin hole 10 to orientate the first carrier board 1 by the aligning mechanism to make sure a position of a lifted board 12; step 103, linearly cutting a lifted board 12, a board having a first circuit board 122 and a plurality of linkage arm 124 which keeps the first circuit board 122 at the lifted board 12, by the cutting machine and making a void part 14 at the first carrier board 1 as FIG. 2 showed; step 104, aligning a plurality of first pin hole 20 to orientate the second carrier board 2 by the aligning mechanism to make sure a position of a replaced board 22; step 105, cutting a replaced board 22, a board having a second circuit board 222 and a plurality of linkage arm 224 which keeps the second circuit board 222 at the replaced board 22, by the cutting machine as FIG. 3 showed to make a contour of the replaced board 22 be matched with the void part 14 of the first carrier board 1; step 106, positioning the replaced board 22 at the void part 14 of the first carrier board 1 by the aligning mechanism; and step 107, combining the replaced board 22 with the first carrier board 1 at the void part 14 by the assembling machine to complete the first carrier board 1 as FIG. 2 showed.

The said cutting machine can be selected from a CNC (computing numerical control) center. A means for cutting at the cutting machine is a cutting mechanism which is selected from one of a CNC machine, a laser machine, and a die machine.

The said aligning mechanism has a means for image process and a means for positioning. The image process means can has at least a camera which is selected from one of a CMOS camera, a CCD camera, a Super CCD camera, and VPS camera. The means for positioning can be a mechanism which has a grip to catch said elements and make two elements at determined positions according with the process.

In an embodiment, the second circuit board 222 is a normal circuit board which has a original function for which the first circuit board 122 is designed while the first circuit board 122 has a defect. Therefore, the first circuit board 122 of the first carrier board 1 can be replaced with the second circuit board 222 to repair the first carrier board 1 or to make the first carrier board 1 complete.

Base on the present invention said above, if the first carrier board 1 related to the present invention has more first circuit boards 122, the method of the present invention still works and each first circuit board 122 can be replaced with a second circuit board 222 of the replaced board to make the first carrier board 1 complete.

It is noticeable that the cutting machine has vertical process for severing the first carrier board 1 and second carrier board 2. Actually, the vertical process of the cutting machine is substituted with any cutting method but increasing assembly of replaced board 22 and first carrier board 1.

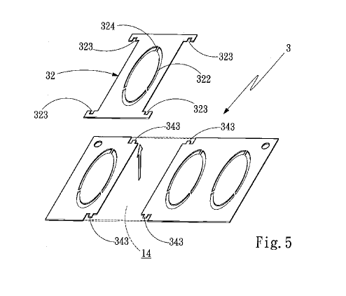

With reference to FIG. 5, each cutting process of the carrier board of the present invention makes the carrier board be engaged with the replaced board. In an embodiment, the cutting machine cuts a first carrier board 3 vertically to release a scrapped area so that the first carrier board 3 has a void part 34. A replaced board 32 is made from another carrier board by the same cutting process which produces the void part 34 of the first carrier board 3. The replaced board 32 has a second circuit board 322 and a plurality of linkage arm 324 which keeps the first circuit board 322 at the replaced board 32, and the replaced board 32 has a first engaged structure 323 at an outline thereof. Moreover, at an outline of the void part 34 the first carrier board 3 has a second engaged structure 343 according to the first engaged structure 323 of the replaced board 32 so that the replaced board 32 combines with the first carrier board 3 at the void part 34 by engagement of the first circuit board 322 and the second engaged structure 343. Besides, the first engaged structure 323 and the second engaged structure 343 can be contoured to any type of a parabola surface, a streamline surface, a sawtooth surface, a protruded surface, and a rhombus surface.

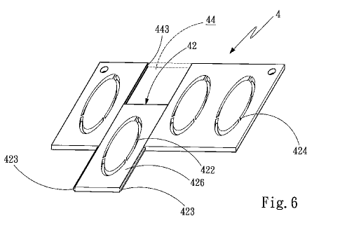

In another embodiment with reference to FIG. 6, each cutting process of the carrier board of the present invention makes the carrier board be engaged with the replaced board. The cutting machine cuts a first carrier board 4 horizontally to release a scrapped area so that the first carrier board 4 has a void part 44. A replaced board 42 is made from another carrier board by the same cutting process which produces the void part 44 of the first carrier board 4. The replaced board 42 has a second circuit board 422 and a plurality of linkage arm 424 which keeps the first circuit board 422 at the replaced board 42, and the replaced board 42 has a first engaged structure 423 at an outline thereof. Moreover, at an outline of the void part 44 the first carrier board 4 has a second engaged structure 443 according to the first engaged structure 423 of the replaced board 42 so that the replaced board 42 combines with the first carrier board 4 at the void part 44 by engagement of the first circuit board 422 and the second engaged structure 443. Besides, the first engaged structure 323 and the second engaged structure 343 can be contoured to any type of a parabola surface, a streamline surface, a sawtooth surface, a protruded surface, and a rhombus surface.

The said vertically cutting is that the cutting path is normal to a surface of the carrier board while the said horizontally cutting is that the cutting path is parallel to the surface of the carrier board.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A method for partial replacement of a circuit board, comprising:
providing a first carrier board and a replaced board which has a second circuit board and a plurality of linkage arm which keeps the second circuit board at the replaced board;
cutting a lifted board from the first carrier board to make a void part at the first carrier board; and
combining the replaced board with the first carrier board at the void part.

2. The method for partial replacement of a circuit board as claimed in claim 1, wherein further comprising cutting the replaced board from a second carrier board to make a contour of the replaced board be matched with the void part of the first carrier board.

3. The method for partial replacement of a circuit board as claimed in claim 1, wherein the process of cutting the lifted board is a vertical cutting at a surface of the first carrier board.

4. The method for partial replacement of a circuit board as claimed in claim 1, wherein the cutting processes makes the replaced board have contour engaged with the void part of the first carrier board.

5. The method for partial replacement of a circuit board as claimed in claim 4, wherein the replaced board and the void part of the first carrier board are engaged by an engaged mechanism which are constructed from inclined planes at the replaced board and the void part.

6. The method for partial replacement of a circuit board as claimed in claim 4, wherein the replaced board and the void part of the first carrier board respectively have engaged contours selected from any one of a parabola surface, a streamline surface, a sawtooth surface, a protruded surface, and a rhombus surface.

7. The method for partial replacement of a circuit board as claimed in claim 4, wherein the process of cutting the lifted board is a vertical cutting at a surface of the first carrier board.

8. The method for partial replacement of a circuit board as claimed in claim 4, wherein the process of cutting the lifted board is a horizontal cutting at a surface of the first carrier board.

9. A circuit board, comprising:
a carrier board; and
a replaced board which has a circuit board and a plurality of linkage arm which keeps the circuit board at the replaced board.

10. The circuit board as claimed in claim 9, wherein the replaced board is engaged with the carrier board.

11. The circuit board as claimed in claim 10, wherein a contour of the replaced board engaged with the carrier board is selected from any one of a parabola surface, a streamline surface, a sawtooth surface, a protruded surface, and a rhombus surface.

12. The circuit board as claimed in claim 10, wherein the replaced board and the carrier board are engaged by an inclined plane of the replaced board and another inclined plane of the carrier board.
